(19) United States
(12) Patent Application Publication
(10) Pub. No.: US 2026/0190187 A1
(43) Pub. Date: Jul. 2, 2026

(54) SUBSTRATE HEATER AND SUBSTRATE PROCESSING APPARATUS USING THE SAME

(71) Applicant: ASM IP Holding B.V., Almere (NL)

(72) Inventors: HyeanGi Oh, Gumi-si (KR); Gopu Krishna, Hwaseong-si (KR); Dongok Shin, Suwon (KR); DaeYoun Kim, Seo-gu (KR); Jeongsu Lee, Pyeongtaek-si (KR)

(21) Appl. No.: 19/432,299

(22) Filed: Dec. 24, 2025

Related U.S. Application Data
(60) Provisional application No. 63/739,730, filed on Dec. 30, 2024.

(51) Int. Cl. H05B 6/04; H05B 6/64; H10P 72/00

(52) U.S. Cl. CPC H05B 6/04; H05B 6/6491; H10P 72/0432

(57) ABSTRACT

Substrate heater structure and a substrate processing apparatus using the same are presented. According to an embodiment, the heater structure comprising: a heater plate configured to support a substrate placed upon the heater plate, the heater plate comprises a heating material configured to heat up the heater plate and the substrate; a shaft disposed below the heater plate and configured to support the heater plate, the shaft comprises a cylinder-shaped shaft wall; a plurality of radio frequency (RF) rods disposed inside of the cylinder-shaped shaft wall and configured to transmit an RF power to the heater plate; a plurality of heater rods disposed inside of the cylinder-shaped shaft wall and configured to transmit an electrical energy to the heating material in the heater plate to heat up the heating material, wherein the plurality of RF rods and the plurality of heater rods do not touch each other.

### CROSS-REFERENCE TO RELATED APPLICATIONS

This application claims priority to U.S. Provisional Patent Application Ser. No. 63/739,730 filed Dec. 30, 2024 titled SUBSTRATE HEATER AND SUBSTRATE PROCESSING APPARATUS USING THE SAME, the disclosure of which is hereby incorporated by reference in its entirety.

### FIELD OF INVENTION

The present disclosure relates generally to a substrate heater, more particularly to a substrate heater with multiple radio frequency (RF) rods for effective RF power delivery for substrate processing.

### BACKGROUND OF THE DISCLOSURE

Demands of new and more sophisticated chips in semiconductor industry have been increasing. Due to the demands, the conditions required from reaction chambers for processing substrates may be getting more strict.

To satisfy the stricter conditions such as a higher radio frequency (RF) environment, the RF power delivery to the reaction chamber needs to be improved. Moreover, the parasitic plasmas in the chamber may need to be minimized and an impedance of the chamber may need to be lowered and even.

The present disclosure presents a substrate heater structure and a substrate processing apparatus using the substrate heater so that the strict conditions mentioned above are to be met.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a heater structure for a substrate processing apparatus, the heater structure comprising: a heater plate configured to support a substrate placed upon the heater plate, the heater plate comprises a heating material configured to heat up the heater plate and the substrate; a shaft disposed below the heater plate and configured to support the heater plate, the shaft comprises a cylinder-shaped shaft wall; a protective material configured to cover an inside of the shaft wall; a plurality of radio frequency (RF) rods disposed inside of the cylinder-shaped shaft wall and configured to transmit an RF power to the heater plate; a plurality of heater rods disposed inside of the cylinder-shaped shaft wall and configured to transmit an electrical energy to the heating material in the heater plate to heat up the heating material, wherein the plurality of RF rods and the plurality of heater rods do not touch each other.

In an aspect, the heater structure further comprising ceramic tubes, wherein each of the RF rods and heater rods are surrounded by the ceramic tubes respectively.

In an aspect, the protective material comprises stainless steel.

In an aspect, the ratio of the diameter of the shaft to the diameter of the heater plate is larger than 1:6.

In an aspect, each of the RF rods and the heater rods have a predetermined minimum distance to the shaft wall.

In an aspect, the predetermined minimum distance is between 15 mm and 20 mm.

In an aspect, a diameter of each of the plurality of RF rods is equal to or greater than 4 mm.

In accordance with another embodiment there may be provided, a substrate processing apparatus, the apparatus comprising: a reaction chamber for processing substrates; and a susceptor, wherein the susceptor comprises: a heater plate configured to support a substrate placed upon the heater plate, the heater plate comprises a heating material configured to heat up the heater plate and the substrate; a shaft disposed below the heater plate and configured to support the heater plate, the shaft comprises a cylinder-shaped shaft wall; a plurality of radio frequency (RF) rods disposed inside of the shaft wall and configured to transmit an RF power to the heater plate; a plurality of heater rods disposed inside of the shaft wall and configured to transmit an electrical energy to the heating material in the heater plate to heat up the heating material, wherein the plurality of RF rods and the plurality of heater rods do not touch each other.

In an aspect, the susceptor further comprising ceramic tubes, wherein each of the RF rods and heater rods are surrounded by the ceramic tubes respectively.

In an aspect, the susceptor further comprises a protective material, wherein the protective material is configured to cover an inside of the shaft wall.

In an aspect, the protective material comprises stainless steel.

In an aspect, the ratio of the diameter of the shaft to the diameter of the heater plate is bigger than 1:6.

In an aspect, each of the RF rods and the heater rods have a predetermined minimum distance to the shaft wall.

In an aspect, the predetermined minimum distance is between 15 mm and 20 mm.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a substrate processing apparatus with a substrate heater according to an embodiment of the present disclosure.

FIG. 2 illustrates a detailed view of a substrate heater according to an embodiment of the present disclosure.

FIG. 3(a) illustrates a Frequency(MHz)-Impedance(Ω) graph of a conventional substrate heater equipped substrate processing apparatus; (b) illustrates a Frequency(MHz)-Impedance(Ω) graph of a substrate processing apparatus equipped with a substrate heater according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

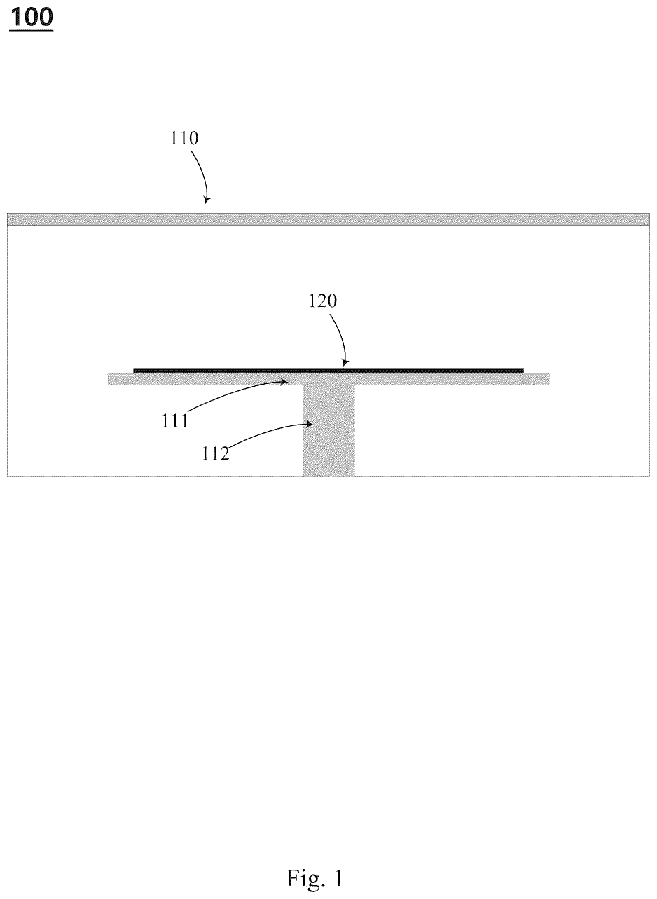

FIG. 1 illustrates an overview of a substrate processing apparatus with a substrate heater according to an embodiment of the present disclosure.

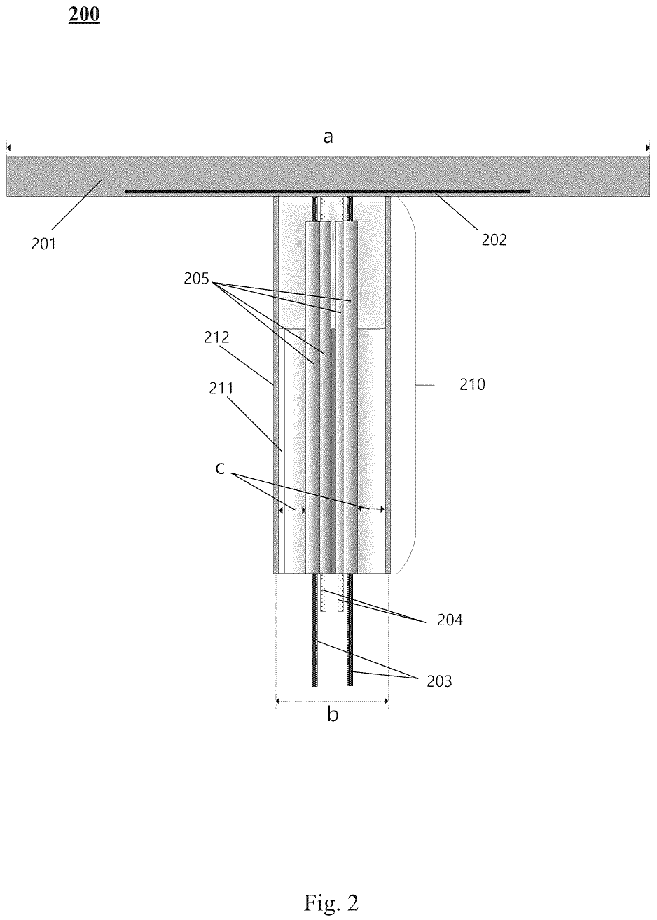

The substrate processing apparatus 100 may comprise a reaction chamber 110, a heater plate 111 and a shaft 112. A substrate 120 may be placed upon the heater plate 111. The heater plate 111 may support and heat up the substrate 120 that is placed upon it. The shaft 112 may support and move the heater plate 111 upwards and downwards. The heater plate 111 and the shaft 112 may be explained in detail in FIG. 2.

FIG. 2 illustrates a detailed view of a substrate heater structure 200 according to an embodiment of the present disclosure.

The substrate heater 200 may comprise a heater plate 201 and a shaft 210. For heating up a substrate which is placed upon it, the heater plate 201 may comprise a heating material 202. The shaft 210 may be disposed below the heater plate 201 and support the heater plate 201. The shaft 210 may be hollow and shaped like a cylinder.

A plurality of radio frequency (RF) rods 203 may be disposed through a hollow of the shaft 210 so that an RF power can be delivered up to the heater plate 201. The number of RF rods may be equal to or greater than 2 (two) for improving an RF power delivery to the reaction chamber through the RF rods. For better improving the RF power delivery efficiency, the diameter of each of the RF rods may be equal to or greater than 4 mm which is thicker than conventionally used RF rod.

A plurality of heater rods 204 may be disposed through the hollow of the shaft 210 along with the RF rods 203 to provide electrical energy to heat up the heating material 202 in the heater plate 201.

The number of heater rods 204 may vary due to the heater material 202 and reaction environment and usually is equal to or greater than 2 (two).

Each of the RF rods 203 and each of the heater rods 204 may be surrounded by ceramic tubes 205 to prevent any RF and/or electro-magnetic leaks or interferences.

A large portion of the inside of the shaft 210 may be covered by a protective material 211 and the protective material 211 may be attached to the inside of the shaft wall 212. The protective material 211 may prevent the formation of bottom parasitic plasma by providing an electromagnetic shielding. For this purpose, the protective material 211 may be steel and/or stainless steel.

The RF rods 203 and heater rods 204 may be arranged inside of the shaft shell 212 so that they are separated with a minimum distance among one another. And the distance “c” from the shaft wall 212 to each of the RF rods 203 and heater rods 204 may be predetermined. The distance (“c”) may be changed to satisfy reaction requirements and the range of the distance (“c”) may be 15 mm and 20 mm. This minimum distance may reduce the parasitic plasma in the bottom area of a reaction chamber.

To enable a high-power & low-pressure process needed for producing more sophisticated semiconductors, a lower chamber impedance may be necessary. To achieve this purpose, the present disclosure provides a wide shaft.

The ratio of a diameter of shaft to a diameter of heater may be around 1/8. However, the ratio of a diameter of the shaft 210 (“b”) to a diameter of the heater plate 201 (“a”) according to an embodiment of the present disclosure is equal to or bigger than 1:6. This increase may result in the lower chamber impedance.

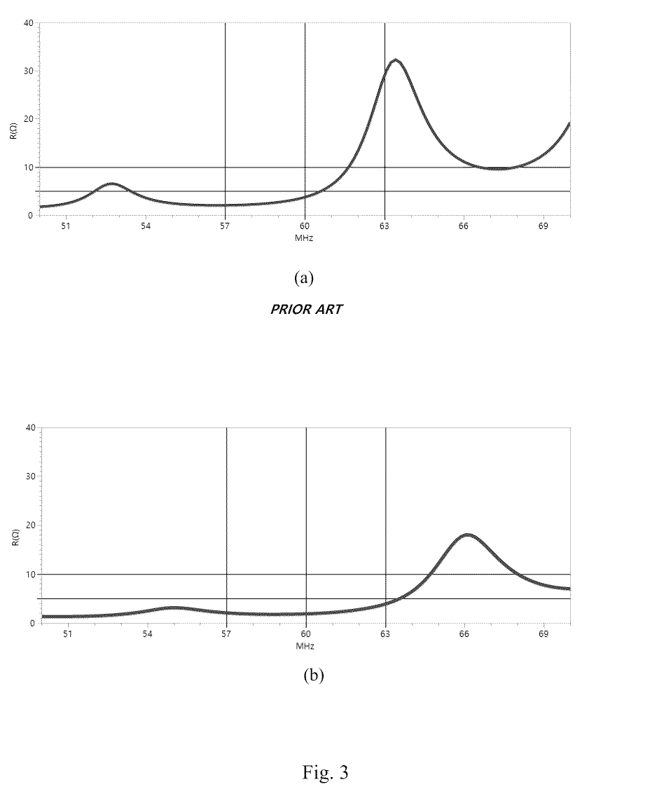

FIG. 3(a) illustrates a Frequency-Impedance graph of a conventional heater plate equipped substrate processing apparatus & FIG. 3(b) illustrates a Frequency-Impedance graph of a substrate processing apparatus equipped with a heater plate according to an embodiment of the present disclosure.

The peak of the impedance around 63 MHz in FIG. 3(a) and around 66 MHz in FIG. 3(b) may be resulted from the different characteristics (for example, shape and/or size) of the respective chambers and shafts.

As illustrated in FIG. 3(a), the impedance in the chamber ranges 5˜30 (Ω) in conventional set-up while the impedance in the chamber illustrated in FIG. 3(b) ranges 5˜20 (Ω). The lowered chamber impedance due to the multiple RF rods and wider shaft of the reaction chamber according to embodiment of the present disclosure may be useful for reactions that require high RF power.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A heater structure for a substrate processing apparatus, the heater structure comprising:
a heater plate configured to support a substrate placed upon the heater plate, the heater plate comprises a heating material configured to heat up the heater plate and the substrate;
a shaft disposed below the heater plate and configured to support the heater plate, the shaft comprises a cylinder-shaped shaft wall;
a protective material configured to cover an inside of the shaft wall;
a plurality of radio frequency (RF) rods disposed inside of the cylinder-shaped shaft wall and configured to transmit an RF power to the heater plate; and
a plurality of heater rods disposed inside of the cylinder-shaped shaft wall and configured to transmit an electrical energy to the heating material in the heater plate to heat up the heating material, wherein the plurality of RF rods and the plurality of heater rods do not touch each other.

2. The heater structure according to claim 1, further comprising ceramic tubes, wherein each of the RF rods and heater rods are surrounded by the ceramic tubes respectively.

3. The heater structure according to claim 1, wherein the protective material comprises stainless steel.

4. The heater structure according to the claim 1, wherein the ratio of the diameter of the shaft to the diameter of the heater plate is bigger than 1:6.

5. The heater structure according to the claim 1, wherein each of the RF rods and the heater rods have a predetermined minimum distance to the shaft wall.

6. The heater structure according to the claim 5, wherein the predetermined minimum distance is between 15 mm and 20 mm.

7. The heater structure according to the claim 1, wherein a diameter of each of the plurality of RF rods is equal to or greater than 4 mm.

8. The heater structure according to claim 1, wherein a number of the RF rods equal to or greater than 2.

9. A substrate processing apparatus, the apparatus comprising:
a reaction chamber for processing substrates; and
a susceptor, wherein the susceptor comprises:
a heater plate configured to support a substrate placed upon the heater plate, the heater plate comprises a heating material configured to heat up the heater plate and the substrate;
a shaft disposed below the heater plate and configured to support the heater plate, the shaft comprises a cylinder-shaped shaft wall;
a plurality of radio frequency (RF) rods disposed inside of the shaft wall and configured to transmit an RF power to the heater plate; and
a plurality of heater rods disposed inside of the shaft wall and configured to transmit an electrical energy to the heating material in the heater plate to heat up the heating material, wherein the plurality of RF rods and the plurality of heater rods do not touch each other.

10. The substrate processing apparatus according to claim 9, the susceptor further comprises ceramic tubes, wherein each of the RF rods and heater rods are surrounded by the ceramic tubes respectively.

11. The substrate processing apparatus according to claim 9, the susceptor further comprises a protective material, wherein the protective material is configured to cover an inside of the shaft wall.

12. The substrate processing apparatus according to claim 9, wherein the protective material comprises stainless steel.

13. The substrate processing apparatus according to claim 9, wherein the ratio of the diameter of the shaft to the diameter of the heater plate is bigger than 1:6.

14. The substrate processing apparatus according to claim 9, wherein each of the RF rods and the heater rods have a predetermined minimum distance to the shaft wall.

15. The substrate processing apparatus according to claim 14, wherein the predetermined minimum distance is between 15 mm and 20 mm.
